(19) United States
(12) Patent Application Publication
(10) Pub. No.: US 2006/0091495 A1
(43) Pub. Date: May 4, 2006

(54) Ceramic thin film on base metal electrode

(76) Inventors: Cengiz A. Palanduz, Chandler, AZ (US); Yongki Min, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/976,425

(22) Filed: Oct. 29, 2004

(51) Int. Cl. H01L 29/00

(52) U.S. Cl. 257/532

(57) ABSTRACT

A method including forming a first metal material layer on a dielectric material; transitioning a portion of the first metal material adjacent to the dielectric to a first oxidation state and a portion of the metal material peripheral to the dielectric material to a second different oxidation state; and forming a second metal material layer on the first metal material. An apparatus including an interposer substrate including an adhesion layer including a metal material having respective portions including at least two different oxidation states; and a capacitor on the adhesion layer. A system including a computing device including a microprocessor, the microprocessor coupled to a printed circuit board through an interposer including an interposer substrate, a capacitor, and an adhesion layer between the interposer substrate and the capacitor, the adhesion layer including a metal material having respective portions including at least two different oxidation states.

### BACKGROUND

1. Field

Integrated circuit structure and packaging.

2. Background

It is desirable to provide decoupling capacitance in a close proximity to an integrated circuit chip or die. The need for such capacitance increases as the switching speed and current requirements of chips or dies becomes higher. One way to provide decoupling capacitance through a chip or die is through an interposer substrate between a chip and a package. Utilizing an interposer substrate between a chip and a package allows capacitance to be approximate to a chip without utilizing real estate on a chip or an associated substrate package. Such configuration tends to improve the capacitance on power supply lines for the chip.

In terms of an interposer substrate, capacitance may be provided through the use of thin film capacitors. Representatively, a platinum material in the form of patterned sheets may form the electrodes and a dielectric material (e.g., metal oxide materials) may be formed between the electrodes. Typically, a capacitor is formed on an interposer substrate of a dielectric material. To make the transition between a dielectric material of an interposer substrate and a conductive material of the capacitor, an adhesion layer may be formed below.

### BRIEF DESCRIPTION OF THE DRAWINGS

Features, aspects, and advantages of embodiments will become more Thoroughly apparent from the following detailed description, appended claims, and accompanying drawings in which:

FIG. 1 shows a cross-sectional view of an interposer substrate mounted between a die as a base substrate.

FIG. 2 shows a magnified view of a portion of interposer substrate of FIG. 1.

FIG. 3 shows a flow chart of a method of forming an adhesion layer on an interposer substrate.

FIG. 4 shows an interposer substrate having an adhesion layer formed thereon according to the method of FIG. 3.

FIG. 5 shows a flow chart of a method of forming a capacitor on an interposer.

### DETAILED DESCRIPTION

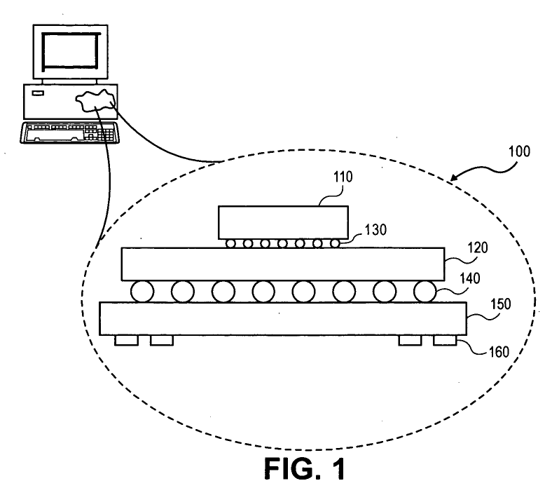

FIG. 1 shows a cross-sectional side view of an interposer substrate mounted between a die and a base substrate. FIG. 1 shows assembly 100 including die or chip 110, interposer substrate 120 and base substrate 150. The assembly may form part of an electronic system such as a computer (e.g., desktop, laptop, hand-held, server, Internet appliance, etc.), a wireless communication device (e.g., cellular phone, cordless phone, pager), a computer-related peripheral (e.g., printer, scanner, monitor), an entertainment device (e.g., television, radio, stereo, tape player, compact disk player, video cassette recorder, MP3 (Motion Picture Experts Group, Audio Layer 3 player) and the like.

In the embodiment shown in FIG. 1, die 110 is an integrated circuit die, such as a processor die. Electrical contact points (e.g., contact pads) on a surface of die 110 are connected to interposer 120 through conductive bump layer 130. Base substrate 150 is, for example, a package substrate, that may be used to connect assembly 100 to a printed circuit board, such as a motherboard or other circuit board. Interposer 120 is electrically connected to base substrate 150 through conductive bump layer 140 that aligns, for example, contact pads on a surface of interposer 120 with contact pads on the surface of base substrate 150. FIG. 1 also shows surface mount capacitors 160 that may optionally be connected to base substrate 150.

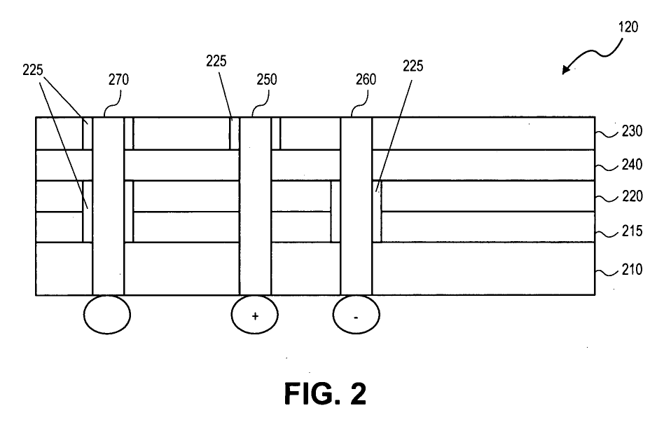

In one embodiment, interposer 120 includes a capacitor structure. FIG. 2 shows a magnified view of a portion of interposer 120. Interposer 120 includes interposer substrate 210, adhesion layer 215 disposed on interposer substrate 210, first conductive layer 220 (electrically conductive) disposed on adhesion layer 215, dielectric layer 240 disposed on first conductive layer 220, and second conductive layer 230 (electrically conductive) disposed on dielectric layer 240.

In one embodiment, interposer substrate 210 is a ceramic interposer. Interposer substrate 210 is, for example, a ceramic material having a relatively low dielectric constant. Representatively, a low dielectric constant (low-k) material is a ceramic material having a dielectric constant on the order of 10 or less. Suitable materials include, but are not limited to, a glass ceramic or aluminum oxide (e.g., Al₂O₃).

In one embodiment, first conductive layer 220 and second conductive layer 230 are selected from a material that may be deposited to a thickness on the order of a few microns or more. A suitable material includes, but is not limited to, platinum. In one embodiment, dielectric layer 240 is a ceramic material having a relatively high dielectric constant (high-k). Representatively, a high-k material is a ceramic material having a dielectric constant greater than 100. In one embodiment, the dielectric layer could have a dielectric constant between 500 and 5000. Suitable materials for dielectric layer 240 include, but are not limited to, barium titanate (BaTiO₃), barium strontium titanate (Ba, Sr) TiO₃, and strontium titanate (SrTiO₃).

In one embodiment, adhesion layer 215 includes a material that may have a number of (e.g., two or more) oxidation states. In this manner, a material for adhesion layer 215 may be oxidized to a greater extent adjacent to interposer substrate 210 and to a lesser extent peripheral to interposer substrate 210, including adjacent first conductive layer 220. Representatively, a material for adhesion layer 215 adjacent to interposer substrate 210 of an oxide (e.g., aluminum oxide) may have bonding capabilities/characteristics similar to a material for interposer substrate 210 (e.g., ionic/covalent bonding). At the same time, a material for adhesion layer 215 adjacent to conductive layer 220 may have bonding capabilities/characteristics similar to a material for conductive layer 220 (e.g., metal bonding). Thus, in one embodiment, to achieve the appropriate bonding capabilities/characteristics an oxidation state of adhesion 215 is transitioned from a portion adjacent interposer substrate 210 to a portion adjacent conductive layer 220. In one embodiment, the transition may occur in two oxidation states. In another embodiment, more than two oxidation states may be employed.

A suitable material for adhesion layer 215 includes, but is not limited to, a transition metal having multiple oxidation states. Transition metals include, but are not limited to, titanium, vanadium, chromium, etc. A material such as titanium, for example, has a number of oxidation states (Ti⁺⁴, Ti⁺³, Ti⁺², Ti⁰).

FIG. 2 shows a number of conductive vias extending through interposer substrate 120. Representatively, conductive via 250 and conductive via 260 are conductive materials (e.g., copper or silver) of different polarity to be connected to power/ground contact points of chip 110 (e.g., through conductive bumps of bump layer 130 to contact pads on die 110 of FIG. 1). In this manner, conductive via 250 and conductive via 260 extend through a high-k material of dielectric layer 240 and a low-k material of interposer substrate 210. FIG. 2 also shows conductive via 270 (e.g., a copper or silver filled via) adjacent a perimeter of interposer 120. Conductive via 270 is aligned to connect with input/output (I/O) signals. In one embodiment, conductive via 270 extends through high-k dielectric layer 240. If layer 240 is one micrometer, an input/output signal would not be significantly distorted by the existence of layer 240. On the other hand, the vias should be insulated (e.g., with insulation rings) from some of the metal layers or potentially conducting adhesion layer, based on the design requirement. In one configuration, insulation rings 225, could be made of SiO₂. Representatively, first conductive layer 220, second conductive layer 230 and adhesion layer 215 are etched away around the perimeter of vias 250, 260 and 270 to prevent shorting of the top and bottom electrodes of the capacitor, and to prevent shorting of the signal via with the capacitor electrodes.

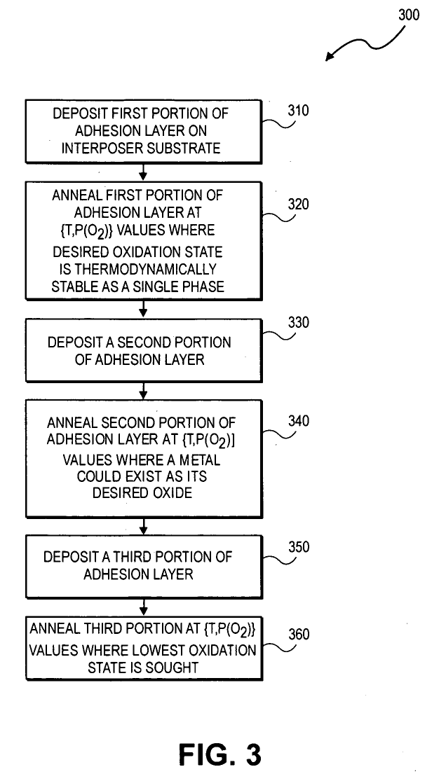

FIG. 3 shows one technique for forming an adhesion layer on an interposer substrate, such as interposer substrate 210. The technique involves the deposition of three layer portions of adhesion layer material. It is appreciated that more or less adhesion layer portions may be deposited as desired. Referring to FIG. 3, method and technique 300 includes initially depositing a first portion of an adhesion layer material, such as a transition metal or an oxide of a transition metal, on an interposer substrate such as interposer substrate 210 (block 310). First portion of an adhesion layer may be deposited to a desired thickness, such as on the order of about 10 nanometers (nm) to 50 nm.

Following the deposition of a first portion of an adhesion layer, technique or method 300 provides annealing the interposer substrate at temperature and partial pressure of oxygen (P(O₂)) to form a desired oxide that is thermodynamically stable as a single phase (block 320). While not wishing to be done by theory, chemical reactions in metallurgical processes such as the reduction of a transition metal such as titanium can be explained in terms of the free energy and thermodynamics. When the free energy of reactant is different from metal and gas products, a reaction will occur. If the reaction leads to a decrease in free energy, it will reach equilibrium when the free energy of the reactant and products become equal. A representation of how changes in the standard Gibb's free energy occur when oxide developments are formed may be represented by an Ellingham diagram. Thus, for the example of an adhesion layer portion of a titanium material, an Ellingham diagram may be used to predict annealing values of temperature and partial pressure of oxygen (P(O₂)) where a titanium oxide (e.g., Ti⁺⁴) is thermodynamically stable as a single phase.

Following the annealing of a first portion of an adhesion layer, technique or method 300 provides depositing a second portion of an adhesion layer (block 330). Following deposition of the second portion of an adhesion layer, the second portion is annealed at a temperature and pressure {T, P(O₂)} where the metal would have to exist as its desired oxide (block 340). For the example of a second portion of an adhesion layer including titanium, a second portion may be annealed at {T, P(O₂)} values where the oxide would exist and the metal would be thermodynamically unstable. In the event where the {T, P(O₂)} values are too extreme, then a thermodynamic equilibrium between two oxides (e.g., two oxides of titanium) having the lowest oxidation state may be sought after.

Following an annealing of a second portion of an adhesion layer, technique or method 300 provides depositing a third portion of an adhesion layer (block 350). Following deposition, the third portion of an adhesion layer may be annealed at {T, P(O₂)} values, under which an oxide having a lowest oxidation state is sought after (block 360). In the case of a third portion of an adhesion layer including titanium, the third portion may be annealed at {T, P(O₂)} values under which an oxide and titanium with a lowest oxidation state is sought after (Ti²⁺ and/or Ti⁰) and is reduced as much as possible to create the largest concentration of free electrons in a conduction band (e.g., Ti⁰).

One way to form different portions of an adhesion layer of a material such as titanium is by sputtering. In the example where the sputtering chamber is used, an oxidation of the material may be accomplished while depositing the material in a sputtering chamber, in which P(O₂) can be controlled.

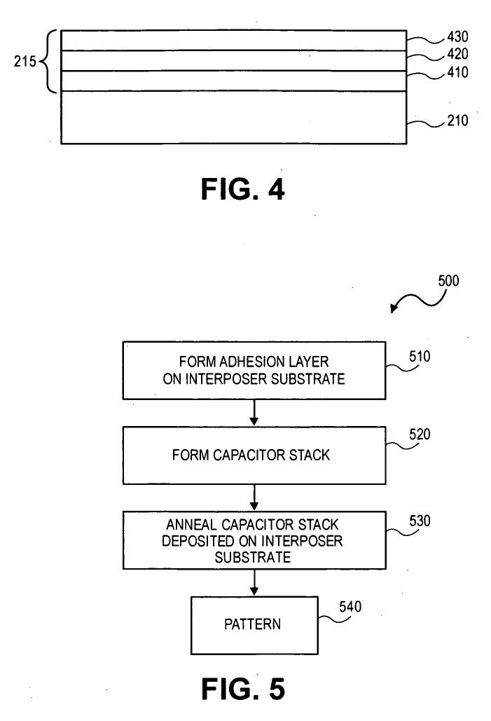

FIG. 4 shows a portion of interposer substrate 210 having an adhesion layer formed on a surface thereof. Representatively, adhesion layer 215 is formed according to the method of FIG. 3. Accordingly, adhesion layer 215 includes first portion 410, second portion 420 and third portion 430. In the example where adhesion layer 215 includes titanium and interposer substrate 210 is an oxide, first portion 410 includes an oxidized titanium material such as Ti⁺⁴. The second portion 420 of adhesion layer 215 may include titanium oxidized to a lesser extent, such as Ti⁺³ and/or Ti⁺². Third portion 430 may include, as much as possible, Ti⁰.

FIG. 5 shows one technique of forming an interposer such as interposer 120. Referring to FIG. 5, method or technique 500 includes forming an adhesion layer on an interposer substrate (block 510). An adhesion layer may be formed as described above according to the method of FIG. 3 and the accompanying text. Subsequently, a first conductor layer such as conductor layer 220 of FIG. 2 would be deposited on the adhesion layer. A high k dielectric material such as hi-k dielectric material 240 of FIG. 2 would be deposited on first conductor layer 220. A second conductor layer such as conductor layer 230 of FIG. 2 would be deposited on the high k dielectric layer. The whole assembly would then be annealed under thermodynamic conditions where the first and second conductor layers would not be oxidized, and the dielectric layer would still be insulating.

Following the annealing of the capacitor stack (e.g., annealing of the high k dielectric), the interposer is patterned (block 540). In one embodiment, the interposer is patterned by forming vias through the interposer, removing high-k ceramic material from the peripheral region, etc.

In the above description, a technique for modifying an adhesion layer of an interposer is described. In one embodiment, modification of the adhesion layer tends to promote improved bonding between different materials, such as a dielectric material (e.g., ceramic) and a metal. It is appreciated that the technique described herein for modifying an adhesion layer or a transition material between materials with different states is not limited to interposer substrate or capacitor. The technique described above may be used wherever, for example, it is desired to bond materials having different bonding characteristics (e.g., ionic, covalent v. metallic).

In the preceding detailed description, reference is made to specific embodiments thereof. It will, however, be evident that various modifications and changes may be made thereto without departing from the broader spirit and scope of the following claims. The specification and drawings are, accordingly, to be regarded in an illustrative rather than a restrictive sense.

What is claimed is:

1. A method comprising:
forming a first metal material layer on a dielectric material;
transitioning a portion of the first metal material adjacent to the dielectric to a first oxidation state and a portion of the metal material peripheral to the dielectric material to a second different oxidation state; and
forming a second metal material layer on the first metal material.

2. The method of claim 1, wherein the dielectric material comprises a first dielectric material, the method further comprising:
forming a second dielectric material layer on the second metal material layer; and
forming a third metal material layer on the second dielectric material layer.

3. The method of claim 1, further comprising prior to transitioning, depositing the first metal material in one of a metallic state and an oxidized state.

4. The method of claim 1, wherein transitioning comprises:
depositing a first portion of the first metal material in one of a metallic state and an oxidized state;
annealing the first portion at a partial pressure of oxygen suitable to render the first portion thermodynamically stable as a single phase;
depositing a second portion of the first metal material in one of a metallic state and an oxidized state; and
annealing the second portion at a partial pressure of oxygen suitable to render the second portion thermodynamically stable as a single phase.

5. The method of claim 4, wherein annealing the second portion comprises annealing at a partial pressure of oxygen under which a lowest oxidation state of the metal material may be achieved.

6. A method comprising:
forming an adhesion layer on an interposer substrate, the adhesion layer comprising a metal material having respective portions comprising at least two different oxidation states; and
forming a capacitor on the adhesion layer.

7. The method of claim 6, wherein the interposer substrate comprises a dielectric material and forming the adhesion layer comprises:
forming a first portion of the metal material adjacent the interposer substrate with an oxidation state greater than a second portion of the metal material peripheral to the interposer substrate.

8. The method of claim 7, wherein forming the first portion comprises:
depositing a first portion of the first metal material in one of a metallic state and an oxidized state; and
annealing the first portion at a temperature and a partial pressure of oxygen suitable to render the first portion thermodynamically stable as a single phase.

9. The method of claim 7, wherein forming the second portion comprises:
anneal the second portion at a temperature and partial pressure of oxygen to maximize the reduction of the metal material.

10. The method of claim 9, wherein the adhesion layer comprises more than portions than the first portion and the second portion.

11. An apparatus comprising:
an interposer substrate comprising an adhesion layer comprising a metal material having respective portions comprising at least two different oxidation states; and
a capacitor on the adhesion layer.

12. The apparatus of claim 11, wherein a first portion of the metal material of the adhesion layer adjacent the interposer substrate comprises an oxidation state greater than a second portion of the metal material peripheral to the interposer substrate.

13. The apparatus of claim 11, wherein the adhesion layer comprises more portions than the first portion and the second portion.

14. A system comprising:
a computing device comprising a microprocessor, the microprocessor coupled to a printed circuit board through an interposer comprising an interposer substrate, a capacitor, and an adhesion layer between the interposer substrate and the capacitor, the adhesion layer comprising a metal material having respective portions comprising at least two different oxidation states.

15. The system of claim 14, wherein a first portion of the metal material of the adhesion layer adjacent the interposer substrate comprises an oxidation state greater than a second portion of the metal material peripheral to the interposer substrate.

16. The system of claim 15, wherein the adhesion layer comprises more portions than the first portion and the second portion.
